(19) United States
(12) Patent Application Publication
(10) Pub. No.: US 2005/0174821 A1
(43) Pub. Date: Aug. 11, 2005

(54) Multi-stage per cell magnetoresistive random access memory

(76) Inventors: YuanKai Zheng, Singapore (SG); Yihong Wu, Singapore (SG); Zai Bing Guo, Singapore (SG); Jin Jun Qiu, Singapore (SG); Ke Bin Li, Singapore (SG); Gu Chang Han, Singapore (SG)

Correspondence Address: MARTINE PENILLA & GENCARELLA, LLP, 710 LAKEWAY DRIVE, SUITE 200, SUNNYVALE, CA, 94085, US

(21) Appl. No.: 10/507,390

(22) PCT Filed: Mar. 7, 2003
(86) PCT No.: PCT/SG03/00045

(30) Foreign Application Priority Data
Mar. 12, 2002 (SG) 200201415-7

(51) Int. Cl. G11C 19/08

(52) U.S. Cl. 365/8

(57) ABSTRACT

A multi-state magnetoresistive random access memory unit (MRAM) having a plurality of memory cells, each of the cells are written to and read from, independently of other cells. The plurality of memory cells comprises a recording layer as a pinned magnetic layer and a read layer as an unpinned layer. The unpinned layer has a higher Curie point than the pinned layer. The pinned layer in an individual cell is heated to near its Curie point and a bit line current and a word line current is used to align the magnetization vector of the recording layer at a plurality of angles relative to the magnetization vector of the read layer.

### FIELD OF THE INVENTION

The present invention relates to a multi-state magnetoresistive random access memory (MRAM) and more particularly to an MRAM that writes data by thermal assisted techniques and reads data using angular dependent magnetoresistance.

### BACKROUND OF THE INVENTION

The storage capacity of MRAMs can be increased either by reducing the size of each cell or increasing the number of states stored in one cell.

Recently a three-level and six-state multi-level MRAM has been described in a paper written by Won-Cheol Jeong et al, “Three-level, six state multi-level magneto-resistive RAM (MRAM), J Appl. Phys 85, No. 8 4782, 1999.

However, the three-level, and six state structure makes it difficult to write a cell independently. In the prior art MRAM, a half-selected writing of a cell will affect the other unselected cell because of the cell's low coercivity.

Another multi-state MRAM structure with memory cells is disclosed in U.S. Pat. No. 6,169,689 (Naji). The free ferromagnetic layer in the MRAM cell structure is used as the recording layer. However, the free ferromagnetic layer has low anisotropy energy. Hence, as the cell size is reduced to increase the storage capacity of the MRAM, the thermal energy will cause the MRAM to become unstable.

Recently, a Curie point written (CPW) MRAM has been proposed to improve the MRAM stability, as described in the paper by R. S. Beech et al, “Curie point written magnetoresistive memory”. J. Appl. Phys. 87, No. 9, 6403-6405, 2000. The paper discusses a two state Curie point written structure. In this structure, the pinned layer is a storage layer. The pinned layer has a higher anisotropy than the soft unpinned layer. The use of the pinned layer for information storage provides improved thermal stability allowing the cell size to be reduced before thermal instability becomes a limiting factor.

One drawback of the proposed CPW MRAM is, it is difficult to heat and write to individual cells in the MRAM structure. The prior CPW MRAM does not allow individual cells to be selected when the cells are heated to their Curie Point. The current through the sense line and the word line heats the cells. However, as the current passes through the sense and word lines it also heats neighbouring cells and induces a magnetic field in those cells.

### OBJECT OF THE INVENTION

Accordingly it is an aim of the invention to provide multi-state MRAM cells which are capable of being written to or read from independently.

A further aim of the invention is to provide a new and improved multi-state MRAM which is thermally stable.

### SUMMARY OF THE INVENTION

In one form, although it need not be the only or indeed the broadest, the invention resides in a multistate magnetoresistive random access memory (MRAM) unit comprising:
a substrate,
a plurality of memory cells formed on said substrate,
a bit line and a word line in electrical contact with said plurality of memory cells,
each of said plurality of memory cells including a first magnetic layer, a second magnetic layer and a non-magnetic space layer,
wherein a heat element adjacent an individual cell in said plurality of memory cells heats said first magnetic layer of said cell to near its Curie point independently of other cells, and
the magnetization vector of said first magnetic layer is aligned with a magnetic field generated by a current applied to the bit line and the word line.

In a preferred form of the invention the plurality of memory cells is a plurality of stacked cells including a magnetic tunnel junction cell (MTJ), or a spin-valve cell (SV) or a pseudo spin-valve (PSV) cell.

In a further aspect of the invention, there is provided a method of writing data in a magnetoresistive random access memory (MRAM) unit comprising a plurality of memory cells, a bit line and a word line in electrical contact with said plurality of memory cells, a heat element adjacent an individual cell in said plurality of memory cells, the method including the steps of:
raising the temperature of a first magnetic layer in said individual cell to near its Curie point independently of other cells, thereby reducing the coercivity of said layer;
writing a magnetization state in said first magnetic layer of said individual cell by passing a current through said bit line and said word line,
the current in said bit line and said word line acting cooperatively to align the magnetization vector in said first magnetic layer with a magnetic field generated by said current.

In another aspect of the invention, there is provided a method of performing a read operation in a magnetoresistive random access memory (MRAM) unit comprising a plurality of memory cells, a bit line and a word line in electrical contact with said plurality of memory cells, a heat element adjacent an individual cell in said plurality of memory cells, the method including the steps of:
applying a current through said bit line and said word line,
determining the magnetization state of said first magnetic layer, wherein the resistance states of said first magnetic layer is dependent on the relative angles between the magnetization vectors of said first and second magnetic layers,
said resistance states representing the magnetization states of the MRAM, and
reading data represented by said magnetization states stored in said memory cells.

### BRIEF DESCRIPTION OF THE DRAWINGS

FIG. 1 is a schematic view of the magnetization of a two-state MRAM structure;

FIG. 2 is a schematic view of the magnetization of a four-state MRAM structure;

FIG. 3A is a schematic view of a multi-state (SV) and (PSV) MRAM structure heated by a current along the bit line through the cell, in accordance with a first embodiment of the present invention;

FIG. 3B is an illustration of the cell's configuration of a PSV MRAM;

FIG. 3C is an illustration of the cell's configuration of a SV MRAM;

FIG. 3D is a schematic view of the cell's writing by applying the current along the bit and word lines after the cell heated, in accordance with the first embodiment of the present invention;

FIG. 4A is a schematic view of a multi-state SV and PSV MRAM structure heated by the current through a heat element under the cell, in accordance with a second embodiment of the invention;

FIG. 4B is a schematic view of the cell's writing by applying the current along the bit and word lines after the cell is heated by the heat element, in FIG. 4A;

FIG. 5A is schematic view of a multi-state (MTJ) MRAM structure heated by the current through the MTJ cell, in accordance with a third embodiment of the invention;

FIG. 5B is an illustration of a detailed structure of a MTJ cell;

FIG. 5C is a schematic view of the MTJ cell's writing by applying the current along the bit and word lines after the cell is heated, in accordance the third embodiment of the invention;

FIG. 6A is a schematic view of a multi-state MTJ MRAM structure heated by the current through the MTJ cell and heat element, in accordance with a fourth embodiment of the invention;

FIG. 6B is a schematic view of an equivalent circuit of-multi-state MTJ MRAM structure heated by the current through the MTJ cell and a Zener diode, of FIG. 6A;

FIG. 6C is an illustration of an I-V curve of a Zener diode;

FIG. 6D is a schematic view of the MTJ cell's writing by applying the current along the bit and word lines after the cell heated by the heat element and itself, in accordance with the fourth embodiment of the invention; and

FIG. 7 is a view of the MR-H curves of a four-state MTJ MRAM cell.

### DESCRIPTION OF THE PREFERRED EMBODIMENTS

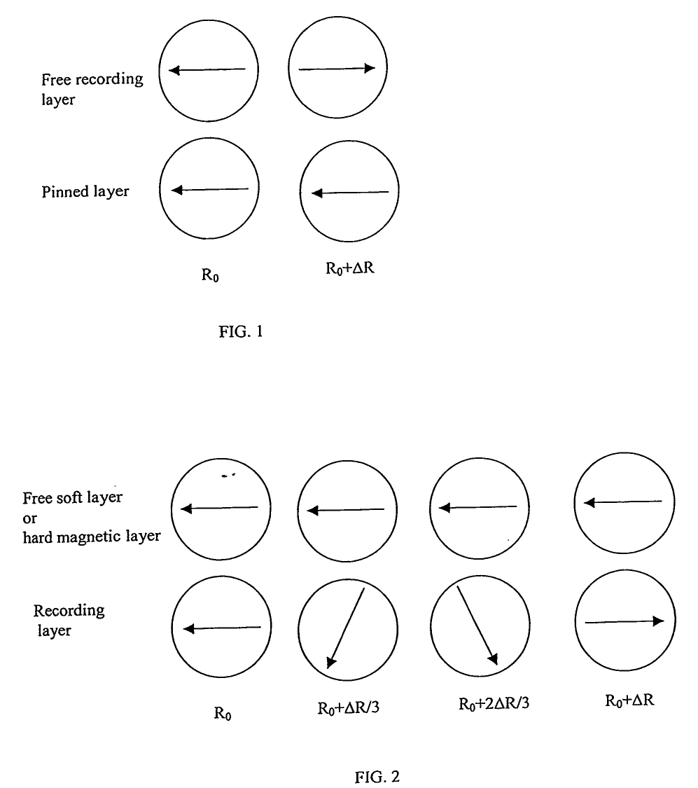

Referring now to the drawings, in FIG. 1 there is generally shown a schematic illustration of the magnetization of a two-state MRAM unit in accordance with the prior art. The pinned layer of a cell in the MRAM is a hard magnetic layer wherein its magnetization is fixed in one direction. The free layer is a soft magnetic unpinned layer whose magnetization direction can be altered. An external field is applied which is induced by a bit current and word current generally (not shown) which can set the free layer's magnetization in one direction. When the magnetization direction of the free layer is parallel to that of the pinned layer, the cell resistance R is low. When the magnetization of the free layer is anti-parallel or misaligned to that of the pinned layer, the cell resistance is high. The relative change in the resistance of the two layers is denoted by ΔR. The low and high resistance can represent two different states in an MRAM read and write operation.

In FIG. 2 there is shown an embodiment of the magnetization of a four-state MRAM structure. The memory cell to be magnetized (not shown) can include SV, PSV or MTJ memory cells. The recording layer is a pinned layer such as CoFe/IrMn or a hard magnetic layer such as TbFeCo, DyFeCo, CoCrPt. The read layer is a soft magnetic layer or hard magnetic layer or pinned magnetic layer. Because of the high anisotropy energy of the recording layer, the magnetization vector of the recording layer can be set to a plurality of angles relative to the magnetization vector of the read layer. The embodiment shown in FIG. 2, illustrates four different angles at which the magnetization vector is set. The angles between magnetization vector of the recording layer relative to the magnetization vector of the read layer are represented by arccos(1), arccos(⅓), arccos(−⅓) and arccos(−1) respectively. The cell resistance R created is dependent on the angle between the magnetization vectors in the recording layer and the read layer. As shown in FIG. 2, when the magnetization vector of the recording layer are parallel or aligned with the magnetization vector of the read layer, the cell resistance is at R₀, substantially zero. The magnetoresistance is therefore denoted by the change in cell resistance, ΔR. Hence, the four resistance states can be determined as approximately R₀, R₀+ΔR/3, R₀+2ΔR/3 and R₀+ΔR, which represent four states in an MRAM read operation.

There are two methods to detect the magnetization state of the recording layer during a read operation. In one method, the magnetization state of the reading layer is not changed. The detected resistance is therefore approximately R₀, R₀+ΔR/3, R₀+2ΔR/3 and R₀+ΔR, respectively for the four conditions. In a preferred method the magnetization of the reading layer is changed from an initial state to being anti-parallel or misaligned with the initial state by a magnetic field induced by a word line current during reading. It is preferred therefore, that the reading layer is a soft magnetic layer, which will allow the magnetization vector to be aligned with the external magnetic field. Hence, as the alignment of the magnetization vector is changed from an initial state, therefore, the cell resistance is changed from the initial state; R₀, R₀+ΔR/3, R₀+2ΔR/3 and R₀+ΔR to; R_{0+ΔR, R}₀+2ΔR/3, R₀+ΔR/3 and R₀ respectively. In this embodiment, the amount of change in the cell resistance is ΔR, +ΔR/3, −ΔR/3 and −ΔR, respectively for the four resistance states.

In the first method, the signal level between the adjacent states is ΔR/3. However, in the second method, the signal level between the adjacent states is 2ΔR/3. As it is apparent the Signal to Noise Ratio (SNR) can be enlarged in the second method, hence more states can be obtained if the signal to noise ratio is sufficiently large. For any given N states per cell MRAM, the magnetization angle of the ith state (i=0 to N-1) between the free layer and recording layer can be set according to the equation arccos (1−[2*i/(N-1)]).

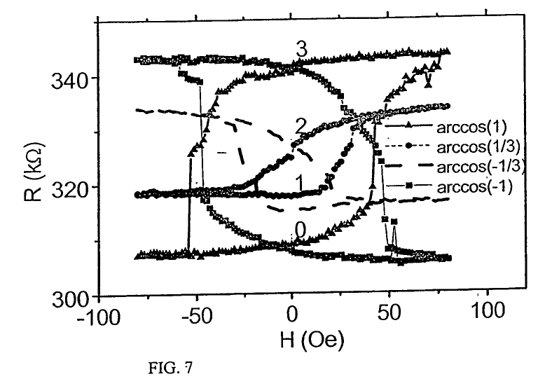

The four states are graphically illustrated in FIG. 7 which shows an MR-H curve of a four state MTJ MRAM cell. In this cell, the read layer is a free layer and the recording layer is a pinned layer. The recording layer is set to be arccos(1), arccos (⅓), arccos (−⅓) and arccos (−1). It is apparent from FIG. 7, that four states can be obtained in the remanent state.

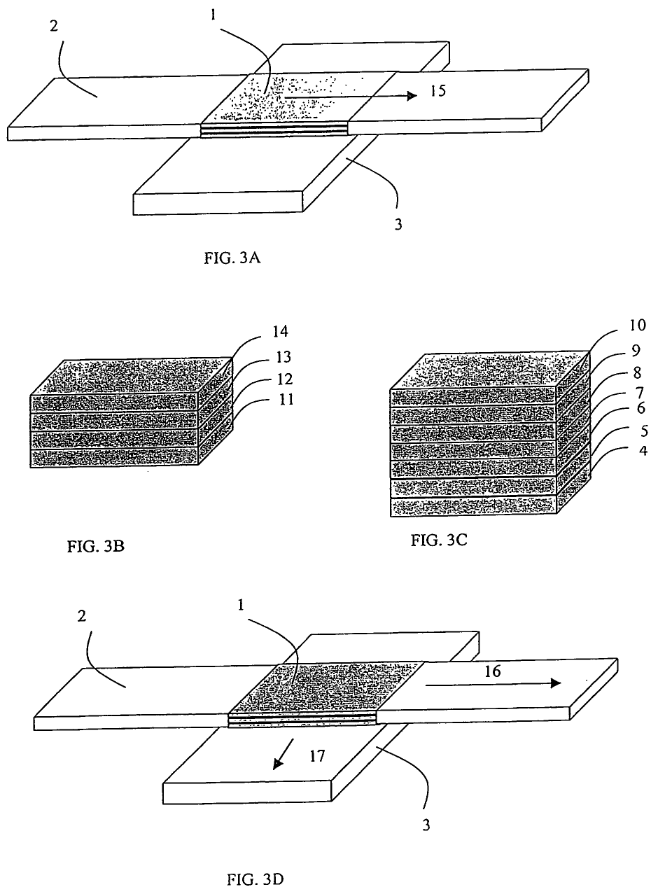

Referring now to FIGS. 3A-3D, an embodiment is shown of the writing operation of magnetization states in a multi-state SV and PSV MRAM unit, in accordance with the invention.

In FIG. 3A there is shown a memory cell 1, a bit line 2 and a word line 3. The memory cell 1 is heated by current 15 present along the bit line 2. In a typical MRAM unit, the memory cell 1 is formed on a substrate (not shown) of the MRAM unit. The bit line 2 and word line 3 are electrically conductive layers also formed on the substrate.

FIG. 3B is a schematic view of the configuration of a PSV MRAM memory cell 1. The PSV cell comprises a recording layer 11 (relatively hard magnetic layer such as thick CoFe), non-magnetic spacing layer 12 (such as Cu), read layer 13 (soft magnetic layer, such as thin CoFe, NiFe) and cap layer 14 (such as Ta).

In FIG. 3C there is shown a configuration of an SV MRAM cell. The SV cell comprises a buffer layer 4 (such as Ta), seed layer 5 (such as NiFe), antiferromagnetic (AFM) layer 6 (such as IrMn, FeMn), pinned layer 7 (such as CoFe), non-ferromagnetic spacing layer 8 (such as Cu), free layer 9 (such as CoFe/NiFe) and capping layer 10 (such as Ta).

Referring to FIG. 3A, in operation, the cell 1 is heated by applying a current 15 through the cell. When the temperature of recording layer nears its Curie point, the coercivity of the recording layer will decrease to be near zero. A small magnetic field induced by the current 15 will change the magnetization of the recording layer. After the temperature of the heated cell drops to room temperature, the magnetization vector of the recording layer will be maintained to the set direction. The recording layer is a pinned magnetic layer and the read layer is a soft magnetic layer or a pinned layer which has a higher Curie point than the recording pinned layer.

Referring now to FIG. 3D, there is shown an embodiment of a writing process to the cell 1. After the cell 1 is heated, the cell's coercivity will be reduced as described with reference to FIG. 3A. Currents 16 and 17, applied along the bit line 2 and word line 3 respectively, will induce a magnetic field, causing the recording layer's magnetization vector to be changed. As it would be known to one of ordinary skill in the art, the degree of change of the magnetization vector will depend on the amount of current applied and the magnitude of the induced magnetic field.

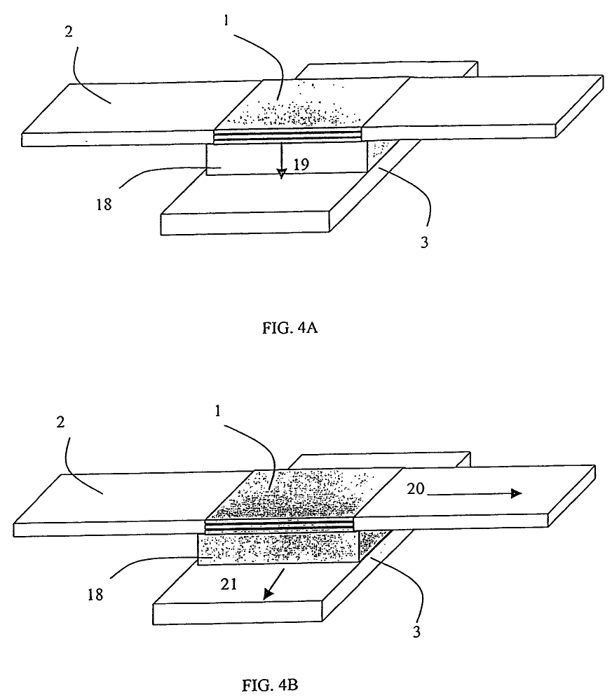

In a further embodiment, a heat element 18 is provided under the cell 1, as shown in FIG. 4A for a multi-state SV and PSV MRAM structure. In order to heat the cell independently, the heat element 18 is placed under or above the cell. When a voltage is applied between the bit line 2 and word line 3, a current 19 will heat the element 18, which will in turn heat the cell.

In FIG. 4B there is shown the cell's writing operation by applying a current 20 along the bit line 2 and the current 21 along the word line 3 after the cell is heated by the heat element 18. The current 20, 21 along the bit line 2 and word line 3 respectively induces a magnetic field which is used to set the magnetization vectors of the recording layer. When the MRAM units are formed into an array, it is possible that the heat element 18 will also partially heat other cells because of the shunting effect. As it will be known to a person of ordinary skill in the art, in order to suppress the shunting effect, a diode or FET transistor or CMOS transistor or other non-linear element (NLE) can be integrated with the heat element.

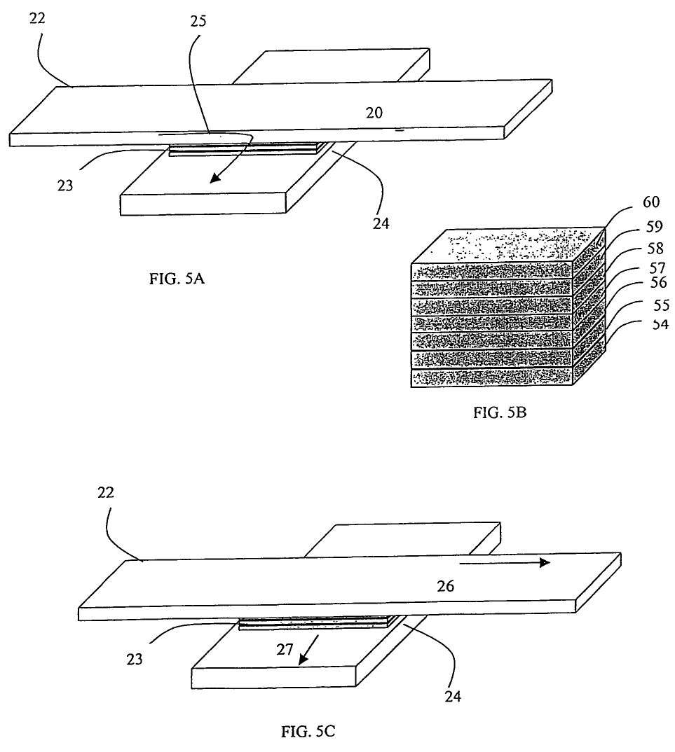

Referring now to FIG. 5A-5C a multi-state MTJ MRAM structure 23 is shown, similar to the SV and PSV structure in FIG. 3. In FIG. 5A the MTJ MRAM comprises a MTJ cell 23, bit line 22 and word line 24. An initial heat current 25 is applied to the MTJ cell 23 by bit line 22 and word line 24. The MTJ cell 23 comprises the following layers: buffer layer 54 (such as Ta), seed layer 55 (such as NiFe), antiferromagnetic (AFM) layer 56 (such as IrMn, FeMn), pinned layer 57 (such as CoFe), non-ferromagnetic insulator layer 58 (such as AlO), free layer 59 (such as CoFe/NiFe) and capping layer 60 (such as Ta).

The writing operation of an MTJ cell 23 in an MRAM is similar to the writing operation of the SV & PSV cell described earlier. FIG. 5C illustrates the cell's writing operation wherein the currents 26, 27 are applied along the but line 22 and word line 24 respectively, after the cell is heated by initial heat current 25.

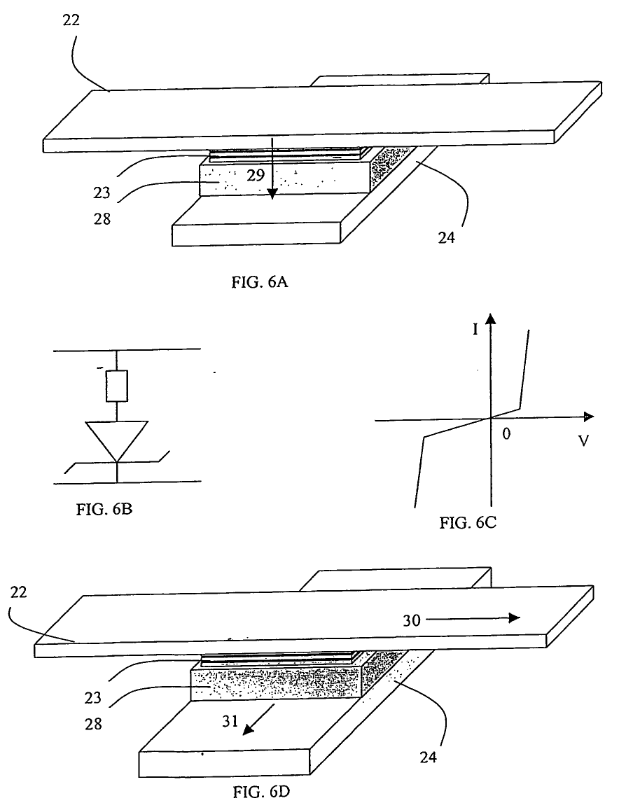

In a further embodiment of a multi-state MTJ MRAM, there is shown in FIG. 6A a MTJ MRAM structure heated by the current 29 through the MTJ cell 23 and heat element 28. The heat element 28 can be a non linear element, such as a Zener diode, FET transistor or any other suitable non-linear element. An equivalent circuit of an MTJ cell integrated with a Zener diode is illustrated in FIG. 6B.

As shown in FIG. 6C, an I-V curve of a Zener diode is illustrated. The maximum heating power (Pₘₐₓ) is equal to V_{d}*V_{b}/Rₘ+V_{b}*V_{b}/Rₘ wherein V_{d} is the voltage applied across the diode, V_{b} is the breakdown voltage of the cell, and Rₘ is the cell resistance. In the forward biased state, the low voltage drop across the diode can be used to select a particular cell during reading. The Zener diode can also serve as a cell selector while writing. The typical voltage drop is about 0.7V and the typical breakdown voltage is about 1 V for a MTJ cell. In operation, the power from these voltage drops may not be sufficient to heat the recording layer. However, in the reverse biased state, the breakdown voltage of the Zener diode can be larger than 4 V. The large voltage drop in this instance can be used to heat the diode, and thereby heat the recording layer. The other unselected diodes in the MRAM are biased below the breakdown voltage, so there is no shunt current flowing through the other unselected cells and diodes. Thus, the shunting effect even while heating the cell can also be suppressed sufficiently by introducing a non-linear element such as Zener diode or other FETS and diodes.

Referring to FIG. 6D, a MTJ cell's writing operation is shown similar to the writing operations described above wherein, currents 30, 31 are applied along bit line 22, and word line 24 respectively, after the cell is heated with heat element 28.

Whilst the present invention has been described with reference to preferred embodiments it should be appreciated that modifications and improvements may be made to the invention without departing from the spirit and scope of the invention as defined in the following claims.

1. A multistate magnetoresistive random access memory (MRAM) unit comprising:
a substrate,
a plurality of memory cells formed on said substrate,
a bit line and a word line in electrical contact with said plurality of memory cells,
each of said plurality of memory cells including a first magnetic layer, a second magnetic layer and a non-magnetic space layer,
wherein a heat element adjacent an individual cell in said plurality of memory cells heats said first magnetic layer of said cell to near its Curie point independently of other cells, and
the magnetization vector of said first magnetic layer is aligned with a magnetic field generated by a current applied to the bit line and word line.

2. The multistate magnetoresistive random access memory unit of claim 1 wherein said first magnetic layer has a first Curie point and said second magnetic layer has a second Curie point that is higher than the first Curie point

3. The multistate magnetoresistive random access memory unit of claim 2 wherein, said first magnetic layer is a recording layer.

4. The multistate magnetoresistive random access memory unit of claim 2 wherein, said second magnetic layer is a read layer.

5. The mulitstate magnetoresistive random access memory unit of claim 2, wherein, said second magnetic layer is a soft magnetic layer,

6. The multistate magnetoresistive random access memory unit of claim 2 wherein the direction of the magnetization vector in said second magnetic layer is changed to an anti-parallel alignment with its initial magnetization vector by the magnetic field generated by the current in the word line during a read operation.

7. The multistate magnetoresistive random access memory unit of claim 2 wherein, the magnetization vector in said first magnetic layer can be aligned at a plurality of angles relative to the magnetization vector of said second magnetic layer.

8. The multistate magnetoresistive random access memory unit of claim 7 wherein the angle between the magnetization vectors of said first and second magnetic layers for an N state per cell MRAM, for the ith state, i=0 to N-1, is represented by the equation:
arccos(1−[2*i/(N-1)]).

9. The multistate magnetoresistive random access memory unit of claim 8 wherein in a four-state MRAM, the angles between the magnetization vectors of said first and second magnetic layers representing each state are, arccos(1), arccos(⅓), arccos(−⅓) and arccos(−1).

10. The multistate magnetoresistive random access memory unit of claim 7 wherein the magnetoresistance of said plurality of memory cells is dependent upon the angles between the magnetization vectors of said first and second magnetic layers.

11. The multistate magnetoresistive random access memory unit of claim 1 wherein the plurality of memory cells are coupled into an array with each cell being individually addressable.

12. The multistate magnetoresistive random access memory unit of claim 11 wherein, said plurality of memory cells is a plurality of stacked cells including a magnetic tunnel junction cell (MTJ), or a spin-valve cell (SV) or a pseudo spin-valve (PSV) cell,

13. The multistate magnetoresistive random access memory unit of claim 12 wherein the non-magnetic space layer is a non-magnetic conductive layer in a SV cell and an insulator tunnelling layer in a MTJ cell.

14. A method of writing data in a magnetoresistive random access memory (MRAM) unit comprising a plurality of memory cells; a bit line and a word line in electrical contact with said plurality of memory cells, a heat element adjacent an individual cell in said plurality of memory cells, the method including the steps of:
raising the temperature of a first magnetic layer in said individual cell to near its Curie point independently of other cells, thereby reducing the coercivity of said layer;
writing a magnetization state in said first magnetic layer of said individual cell by passing a current through said bit line and said word line,
the current in said bit line and said word line acting cooperatively to align the magnetization vector in said first magnetic layer with a magnetic field generated by said current.

15. The method of claim 14 wherein the step of raising the temperature of said first magnetic layer is provided by applying an initial current through said individual cell.

16. The method of claim 15 wherein the initial current is applied to said heat element to heat said individual cell independently of other cells in said plurality of memory cells.

17. The method of claim 14 wherein, said plurality of memory cells is a plurality of stacked cells inducing a magnetic tunnel junction cell (MTJ), or a spin-valve cell (SV) or a pseudo spin-valve (PSV) cell.

18. The method of claim 17 wherein for MTJ memory cells, the heat element is a non-linear element.

19. The method of claim 18 wherein the nonlinear element is provided by a Zener diode in a reversed biased state during writing, connected to the junction of said MTJ memory cells in series.

20. The method of claim 18 wherein said Zener diode acts as a cell selector when in the reverse based state.

21. A method of performing a read operation in a magnetoresistive random access memory (MRAM) unit comprising a plurality of memory cells, a bit line and a word line in electrical contact with said plurality of memory cells, a heat element adjacent an individual cell in said plurality of memory cells, the method including the steps of:
applying a current through said bit line and said word line,
determining the magnetization state of said first magnetic layer, wherein the resistance states of said first magnetic layer is dependent on the relative angles between the magnetization vectors of said first and second magnetic layers,
said resistances states representing the magnetization states of the MRAM, and
reading data represented by said magnetization states stored in said memory cells.

22. The method of claim 21 wherein the resistance for an N state per cell MRAM, for the ith state, i=0 to N-1, is represented by the equation:
R₀+ΔR(i/(N-1))

23. The method of claim 21 wherein the direction of the magnetization vector in a second magnetic layer is changed to an anti-parallel alignment with its initial magnetization vector by a magnetic field generated by the current through said word line.

24. The method of claim 21 wherein the first magnetic layer is a recording layer and the second magnetic layer is a read layer.

25. The method of claim 19 wherein for a spin valve SV) MRAM, the current is applied through said bit line.

26. The method of claim 19 wherein for a magnetic tunnel junction cell (MTJ), the current is applied through said bit line and word line.
